(19) United States
(12) Patent Application Publication
(10) Pub. No.: US 2025/0113575 A1
(43) Pub. Date: Apr. 3, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Tzu-Hung LIU, Yunlin County (TW); Chi-Hsin CHANG, New Taipei City (TW); Chun-Sheng LIANG, Changhua County (TW); Chih-Hao CHANG, Hsin-Chu (TW)

(73) Assignee: Taiwan Semiconductor Manufacturing Company, Ltd., Hsinchu (TW)

(21) Appl. No.: 18/478,086

(22) Filed: Sep. 29, 2023

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/021; H10D 84/013; H10D 84/0135; H10D 84/0147; H10D 84/0151; H10D 84/038; H10D 84/83

(57) ABSTRACT

Semiconductor structures and methods for forming the same are provided. The semiconductor structure includes a plurality of nanostructures formed over a substrate, and a gate structure formed on the nanostructures. The semiconductor structure includes a source/drain (S/D) structure formed adjacent to the gate structure, and a fin spacer layer adjacent to the S/D structure. The bottom surface of the fin spacer layer is lower than a bottom surface of the S/D structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A-1 to 2H-1 illustrate cross-sectional representations of various stages of manufacturing the semiconductor structure shown along line A-A′ in FIG. 1E, in accordance with some embodiments.

FIGS. 2A-2 to 2H-2 illustrate cross-sectional representations of various stages of manufacturing the semiconductor structure shown along line B-B′ in FIG. 1E, in accordance with some embodiments.

FIGS. 2A-3 to 2H-3 illustrate cross-sectional representations of various stages of manufacturing the semiconductor structure shown along line C-C′ in FIG. 1E, in accordance with some embodiments.

FIGS. 2A-4 to 2H-4 illustrate cross-sectional representations of various stages of manufacturing the semiconductor structure shown along line D-D′ in FIG. 1E, in accordance with some embodiments.

FIGS. 3A-1 to 3B-1 illustrate cross-sectional representations of various stages of manufacturing a semiconductor structure shown along line A-A′ in FIG. 1E, in accordance with some embodiments.

FIGS. 3A-2 to 3B-2 illustrate cross-sectional representations of various stages of manufacturing the semiconductor structure shown along line B-B′ in FIG. 1E, in accordance with some embodiments.

FIGS. 3A-3 to 3B-3 illustrate cross-sectional representations of various stages of manufacturing the semiconductor structure shown along line C-C′ in FIG. 1E, in accordance with some embodiments.

FIGS. 3A-4 to 3B-4 illustrate cross-sectional representations of various stages of manufacturing the semiconductor structure shown along line C-C′ in FIG. 1E, in accordance with some embodiments.

FIGS. 4A-1 to 4B-1 illustrate cross-sectional representations of various stages of manufacturing a semiconductor structure shown along line A-A′ in FIG. 1E, in accordance with some embodiments.

FIGS. 4A-2 to 4B-2 illustrate cross-sectional representations of various stages of manufacturing the semiconductor structure shown along line B-B′ in FIG. 1E, in accordance with some embodiments.

FIGS. 4A-3 to 4B-3 illustrate cross-sectional representations of various stages of manufacturing the semiconductor structure shown along line C-C′ in FIG. 1E, in accordance with some embodiments.

FIGS. 4A-4 to 4B-4 illustrate cross-sectional representations of various stages of manufacturing the semiconductor structure shown along line C-C′ in FIG. 1E, in accordance with some embodiments.

FIGS. 5A-1 to 5C-1 illustrate cross-sectional representations of various stages of manufacturing a semiconductor structure shown along line A-A′ in FIG. 1E, in accordance with some embodiments.

FIGS. 5A-2 to 5C-2 illustrate cross-sectional representations of various stages of manufacturing the semiconductor structure shown along line B-B′ in FIG. 1E, in accordance with some embodiments.

FIGS. 5A-3 to 5C-3 illustrate cross-sectional representations of various stages of manufacturing the semiconductor structure shown along line C-C′ in FIG. 1E, in accordance with some embodiments.

FIGS. 5A-4 to 5C-4 illustrate cross-sectional representations of various stages of manufacturing the semiconductor structure shown along line C-C′ in FIG. 1E, in accordance with some embodiments.

FIGS. 6A to 6B illustrate perspective views of intermediate stages of manufacturing a semiconductor structure, in accordance with some embodiments.

FIGS. 7A-1 to 7G-1 illustrate cross-sectional representations of various stages of manufacturing the semiconductor structure shown along line A-A′ in FIG. 6B, in accordance with some embodiments.

FIGS. 7A-2 to 7G-2 illustrate cross-sectional representations of various stages of manufacturing the semiconductor structure shown along line B-B′ in FIG. 6B, in accordance with some embodiments.

FIGS. 7A-3 to 7G-3 illustrate cross-sectional representations of various stages of manufacturing the semiconductor structure shown along line C-C′ in FIG. 6B, in accordance with some embodiments.

FIGS. 8A-1 to 8B-1 illustrate cross-sectional representations of various stages of manufacturing a semiconductor structure shown along line A-A′ in FIG. 6B, in accordance with some embodiments.

FIGS. 8A-2 to 8B-2 illustrate cross-sectional representations of various stages of manufacturing the semiconductor structure shown along line B-B′ in FIG. 6B, in accordance with some embodiments.

FIGS. 8A-3 to 8B-3 illustrate cross-sectional representations of various stages of manufacturing the semiconductor structure shown along line C-C′ in FIG. 6B, in accordance with some embodiments.

FIGS. 9A-1 to 9B-1 illustrate cross-sectional representations of various stages of manufacturing a semiconductor structure shown along line A-A′ in FIG. 6B, in accordance with some embodiments.

FIGS. 9A-2 to 9B-2 illustrate cross-sectional representations of various stages of manufacturing the semiconductor structure shown along line B-B′ in FIG. 6B, in accordance with some embodiments.

FIGS. 9A-3 to 9B-3 illustrate cross-sectional representations of various stages of manufacturing the semiconductor structure shown along line C-C′ in FIG. 6B, in accordance with some embodiments.

FIGS. 10A-1 to 10B-1 illustrate cross-sectional representations of various stages of manufacturing a semiconductor structure shown along line A-A′ in FIG. 6B, in accordance with some embodiments.

FIGS. 10A-2 to 10B-2 illustrate cross-sectional representations of various stages of manufacturing the semiconductor structure shown along line B-B′ in FIG. 6B, in accordance with some embodiments.

FIGS. 10A-3 to 10B-3 illustrate cross-sectional representations of various stages of manufacturing the semiconductor structure shown along line C-C′ in FIG. 6B, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The fin structure is formed on a substrate, and the isolation structure is formed over the substrate. The fin structure includes a number of first semiconductor layers and a number of the second semiconductor layers. A dummy gate structure is formed on the fin structure. The isolation structure includes a first portion which is directly below the dummy gate structure. A portion of the isolation structure which is not covered by the dummy gate structure is removed to form a second portion of isolation structure. The first portion of the isolation structure has a first height, and the second portion of the isolation structure has a second height. The gate spacer layer is formed on sidewall surfaces of the dummy gate structure. At the S/D regions, the top portion of the fin structure is removed to form the S/D recess. The fin spacer layer is formed on the sidewall surface of the fin structure in the S/D regions. Since the second portion of the isolation structure is lower than the first portion, the bottom portion of the fin structure is protected by the fin spacer layer, and the fin structure is not damaged or etched, the S/D structure can be formed in the S/D recess and on the fin structure. Therefore, the performance of the semiconductor structure may be improved. The source/drain (S/D) structure or region(s) may refer to a source or a drain, individually or collectively dependent upon the context.

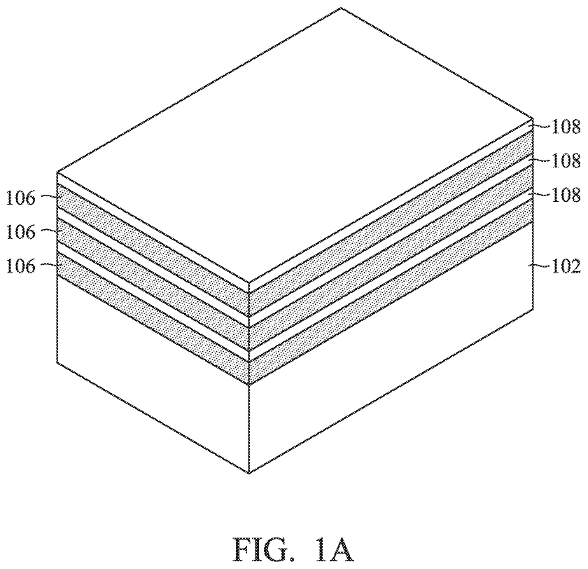

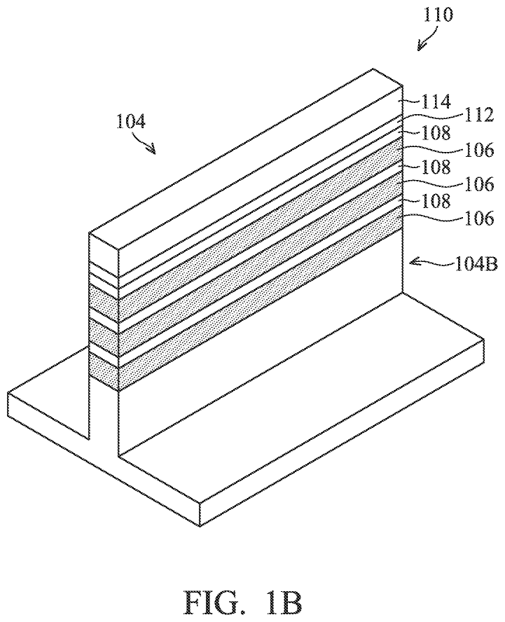

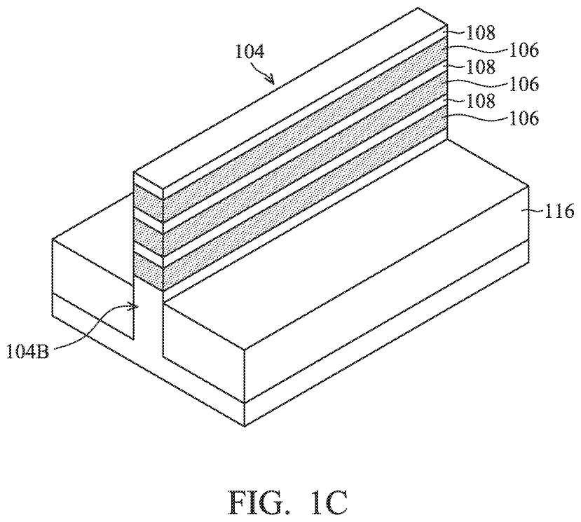

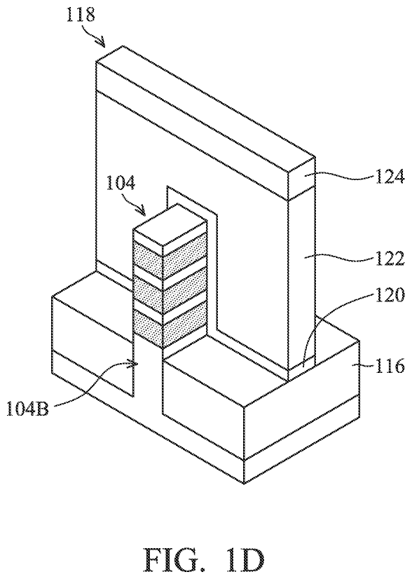

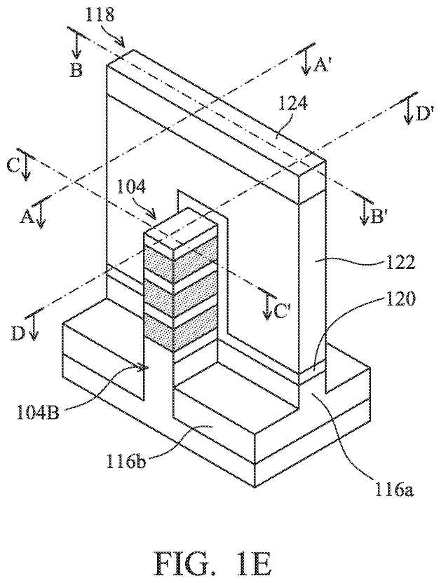

FIGS. 1A to 1E illustrate perspective views of intermediate stages of manufacturing a semiconductor structure 100a in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

As shown in FIG. 1B, after the first semiconductor material layers 106 and the second semiconductor material layers 108 are formed as a semiconductor material stack over the substrate 102, the semiconductor material stack is patterned to form a fin structure 104, in accordance with some embodiments. In some embodiments, the fin structure 104 includes a base fin structure 104B and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

As shown in FIG. 1C, after the fin structure 104 is formed, an isolation structure 116 is formed around the fin structure 104, and the mask structure 110 is removed, in accordance with some embodiments. The isolation structure 116 is configured to electrically isolate active regions (e.g. the fin structure 104) of the semiconductor structure 100 and is also referred to as shallow trench isolation (STI) feature in accordance with some embodiments.

The isolation structure 116 may be formed by depositing an insulating layer over the substrate 102 and recessing the insulating layer so that the fin structure 104 is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

As shown in FIG. 1D, after the isolation structure 116 is formed, a dummy gate structure 118 is formed across the fin structure 104 and extend over the isolation structure 116, in accordance with some embodiments. The dummy gate structure 118 may be used to define the source/drain regions and the channel regions of the resulting semiconductor structure 100.

In some embodiments, the dummy gate structure 118 includes a dummy gate dielectric layer 120 and a dummy gate electrode layer 122. In some embodiments, the dummy gate dielectric layer 120 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 120 is formed using thermal oxidation, chemical vapor deposition (CVD), atomic vapor deposition (ALD), physical vapor deposition (PVD), another suitable method, or a combination thereof.

In some embodiments, the dummy gate electrode layer 122 is made of conductive material. In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layer 122 is formed using chemical vapor deposition (CVD), physical vapor deposition (PVD), or a combination thereof.

In some embodiments, hard mask layer 124 is formed over the dummy gate structure 118. In some embodiments, the hard mask layer 124 includes multiple layers, such as an oxide layer and a nitride layer. In some embodiments, the oxide layer is silicon oxide, and the nitride layer is silicon nitride.

The formation of the dummy gate structure 118 may include conformally forming a dielectric material as the dummy gate dielectric layer 120. Afterwards, a conductive material may be formed over the dielectric material as the dummy gate electrode layer 122, and the hard mask layer 124 may be formed over the conductive material. Next, the dielectric material and the conductive material may be patterned through the hard mask layer 124 to form the dummy gate structure 118.

As shown in FIG. 1E, after the dummy gate structure 118 is formed, a portion of the isolation structure 116 is removed which are not covered by the dummy gate structure 118, in accordance with some embodiments.

After the etching process, the isolation structure 116 includes the first portion 116a which is directly below the dummy gate structure 118 and the second portion 116b which is outside of the dummy gate structure 118. The first portion 116a of the isolation structure 116 has the first height H₁ along the vertical direction, and the second portion 116b of the isolation structure 116 has the second height H₂ along the vertical direction. The first height H₁ is greater than the second height H₂. The top surface of the first portion 116a of the isolation structure 116 is higher than the top surface of the second portion 116b of the isolation structure 116.

In some embodiments, the portion of the isolation structure 116 is removed by the etching process. In some embodiments, the etching process includes using the etching gas, and the etching gas includes fluorine (F)-base compound.

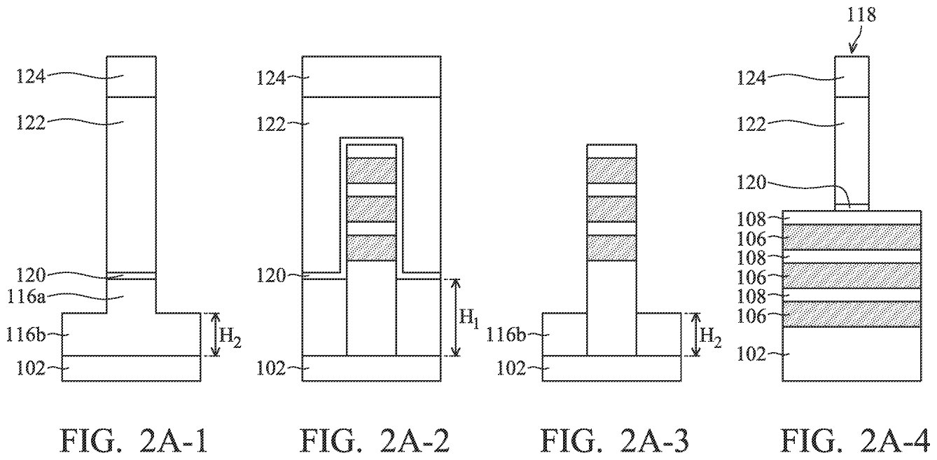

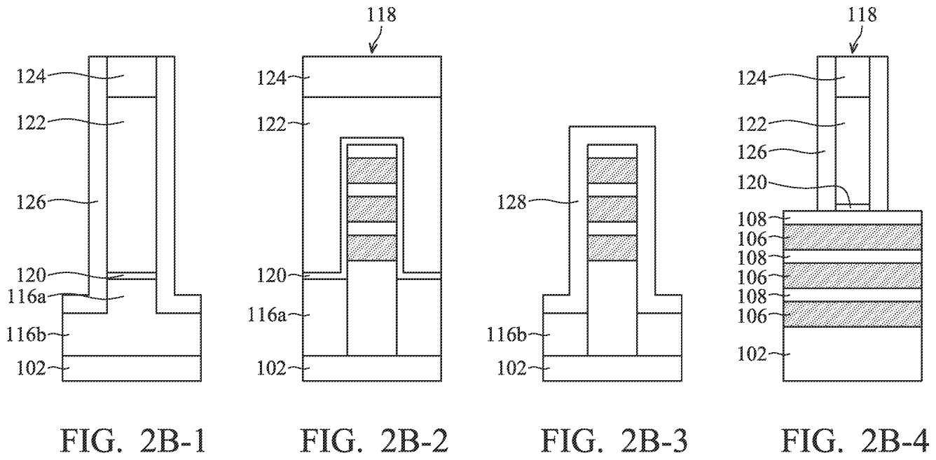

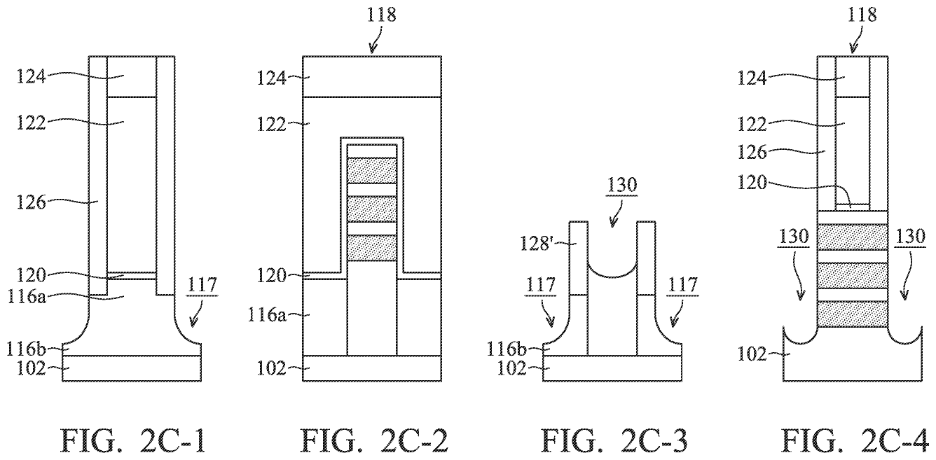

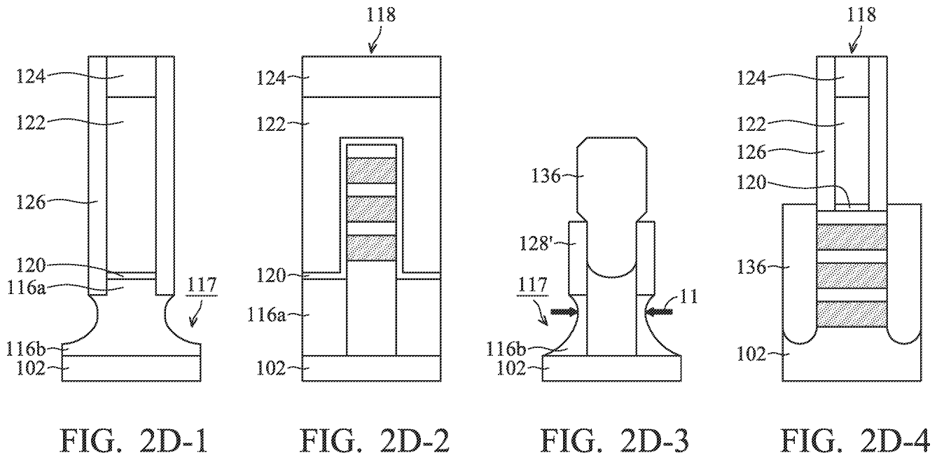

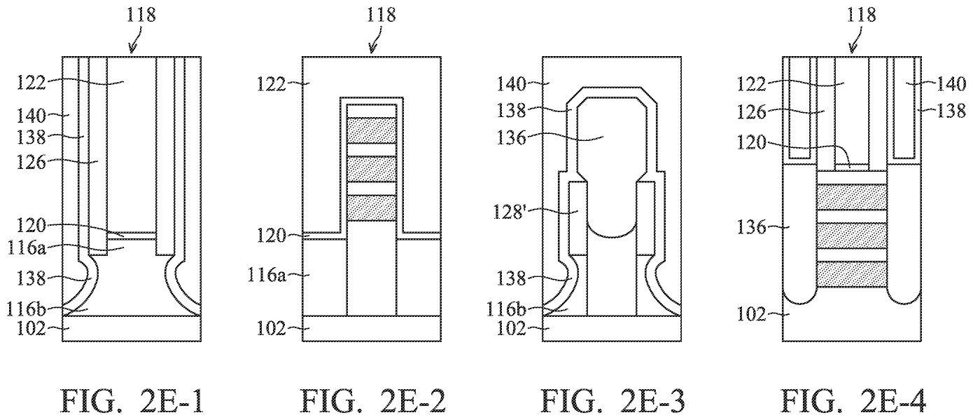

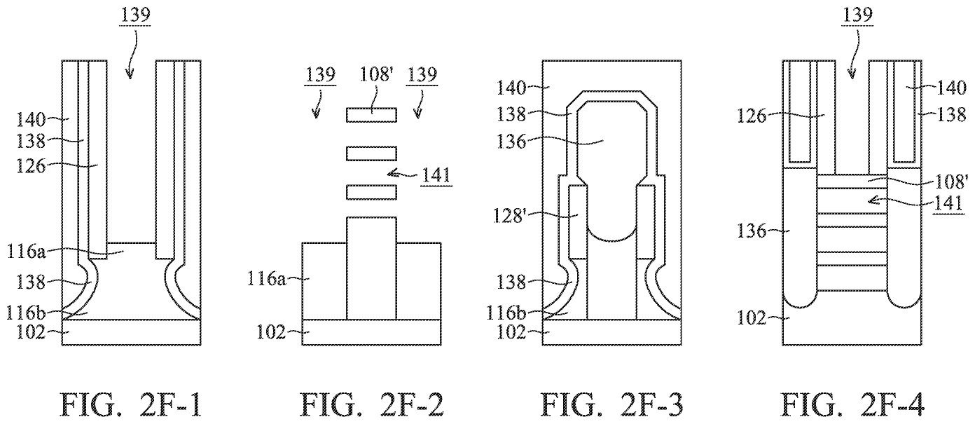

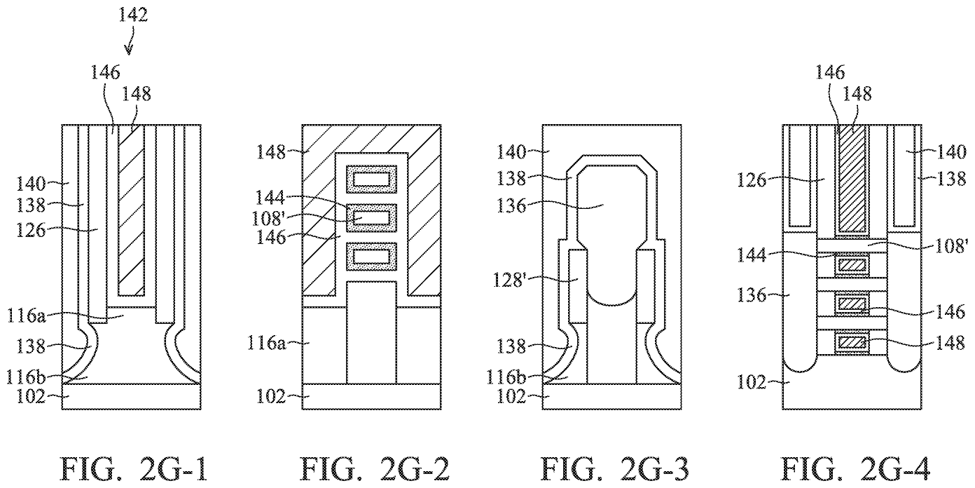

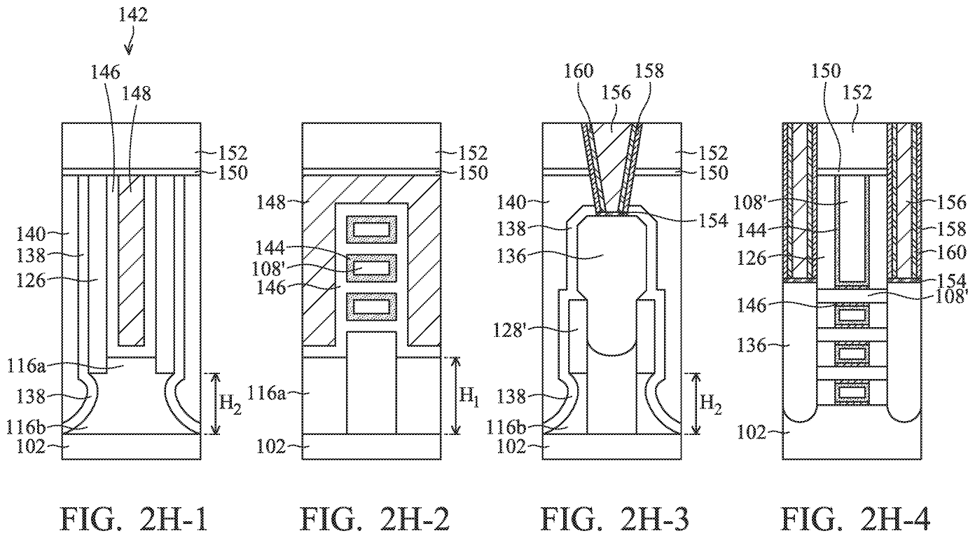

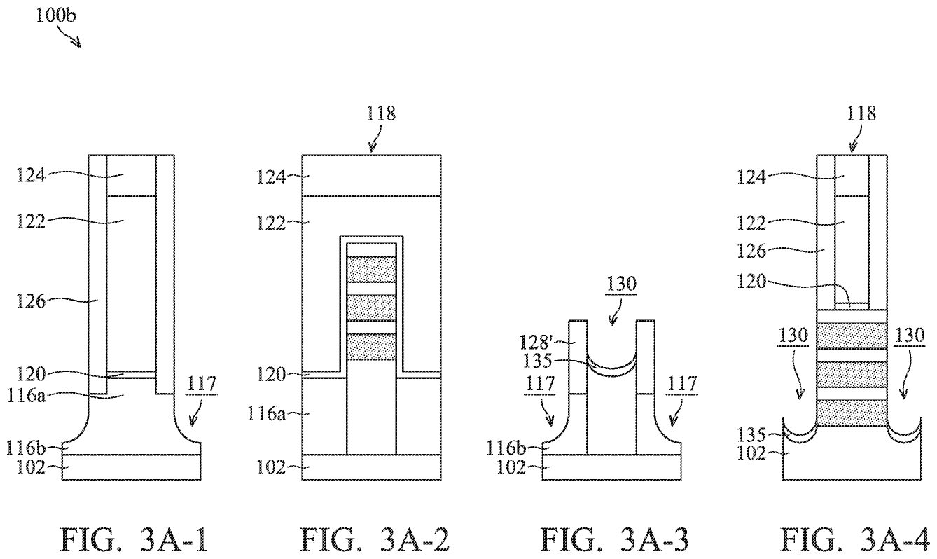

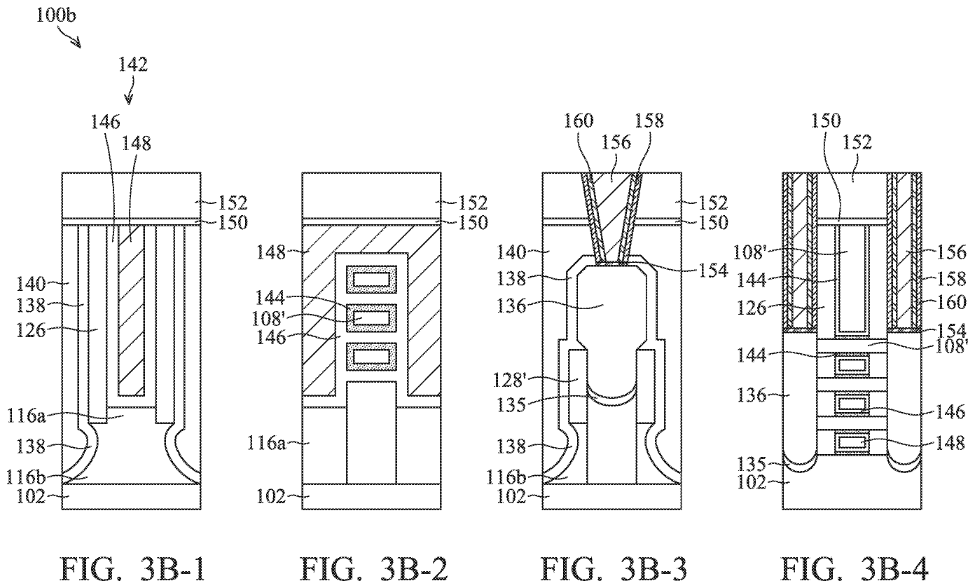

FIGS. 2A-1 to 2H-1 illustrate cross-sectional representations of various stages of manufacturing the semiconductor structure 100a shown along line A-A′ in FIG. 1E, in accordance with some embodiments. FIGS. 2A-2 to 2H-2 illustrate cross-sectional representations of various stages of manufacturing the semiconductor structure 100a shown along line B-B′ in FIG. 1E, in accordance with some embodiments. FIGS. 2A-3 to 2H-3 illustrate cross-sectional representations of various stages of manufacturing the semiconductor structure 100a shown along line C-C′ in FIG. 1E, in accordance with some embodiments. FIGS. 2A-4 to 2H-4 illustrate cross-sectional representations of various stages of manufacturing the semiconductor structure 100a shown along line D-D′ in FIG. 1E, in accordance with some embodiments.

As shown in FIGS. 2A-1, 2A-2, 2A-3 and 2A-4, after the etching process, the first portion 116a of the isolation structure 116 has the first height H₁, and the second portion 116b of the isolation structure 116 has the second height H₂. The first height H₁ is greater than the second height H₂.

Afterwards, as shown in FIGS. 2B-1, 2B-2, 2B-3 and 2B-4, after the etching process, the gate spacer layer 126 are formed along and covering opposite sidewalls of the dummy gate structure 118 and fin spacer layers 128 are formed along and covering opposite sidewalls of the source/drain regions of the fin structure 104, in accordance with some embodiments.

It should be noted that since the second portion 116b of the isolation structure 116 is lower than the first portion 116a of the isolation structure 116, a portion of the gate spacer layers 126 directly formed on the second portion 116b of the isolation structure 116 is lower than the bottom surface of the dummy gate structure 118.

The gate spacer layers 126 may be configured to separate source/drain structures from the dummy gate structure 118 and support the dummy gate structure 118, and the fin spacer layers 128 may be configured to constrain a lateral growth of subsequently formed source/drain structure and support the fin structure 104.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

Next, as shown in FIGS. 2C-1, 2C-2, 2C-3 and 2C-4, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by the dummy gate structure 118 and the gate spacer layers 126 are removed, in accordance with some embodiments.

In addition, a portion of the second portion 116b of the isolation structure 116 is removed while the S/D regions of the fin structure 104 are recessed to form an isolation recess 117. As a result, the second portion 116b of the isolation structure 116 has a curved or recessed sidewall surface.

Furthermore, a portion of the gate spacer layer 126 is removed, and as a result, the bottom surface of the gate spacer layer 126 is lower than the bottom surface of the dummy gate structure 118, as shown in FIG. 2C-1. A portion of the fin spacer layer 128′ is removed to form the fin spacer layers 128′, and as a result, the bottom surface of the fin spacer layer 128′ is lower than the bottom surface of the S/D recess 130, as shown in FIG. 2C-3.

In some embodiments, the fin structure 104 is recessed by performing an etching process. The etching process may be an anisotropic etching process, such as dry plasma etching, and the dummy gate structure 118 and the gate spacer layers 126 are used as etching masks during the etching process.

Afterwards, as shown in FIGS. 2D-1, 2D-2, 2D-3 and 2D-4, after the source/drain recesses 130 are formed, the first semiconductor material layers 106 exposed by the source/drain recesses 130 are laterally recessed to form notches (not shown), and the inner spacer layers 134 are formed in the notches between the second semiconductor material layers 108, in accordance with some embodiments.

In some embodiments, an etching process is performed on the semiconductor structure 100a to laterally recess the first semiconductor material layers 106 of the fin structure 104 from the source/drain recesses 130. In some embodiments, during the etching process, the first semiconductor material layers 106 have a greater etching rate (or etching amount) than the second semiconductor material layers 108, thereby forming notches (not shown) between adjacent second semiconductor material layers 108. In some embodiments, the etching process is an isotropic etching such as dry chemical etching, remote plasma etching, wet chemical etching, another suitable technique, and/or a combination thereof.

The inner spacer layers 134 are configured to separate the source/drain structures and the gate structure formed in subsequent manufacturing processes in accordance with some embodiments.

In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Next, as shown in FIG. 2D-3, before forming the source/drain (S/D) structures 136, a pre-clean process is performed to remove unwanted residue and to have a clean top surface of the fin structure 104. However, during the pre-clean process, the exposed second portion 116b of the isolation structure 116 is also etched by the pre-clean process. As a result, the sidewall surfaces of the second portion 116b of the isolation structure 116 are pushed towards to the fin structure 104 (shown in the arrows 11).

After the pre-clean process, the recessed isolation structure 117 extends into a position which is directly below the gate spacer layer 126. In addition, the recessed isolation structure 117 extends into a position which is directly below the fin spacer layer 128′ after the pre-clean process. In some embodiments, the pre-clean process is performed by using an etching comprising fluorine (F)-based compound.

It should be noted that, the second portion 116b of the isolation structure 116 is also etched by the pre-clean process. If the second portion 116b of the isolation structure 116 is over-removed to expose the fin structure 104, the fin structure 104 will be damaged by the pre-clean process. In order to protect the bottom portion of the fin structure 104, the fin spacer layer 128 is formed on the sidewall surface of the fin structure 104. In addition, since the height of the isolation structure 116 is reduced at FIG. 2A-3, the fin spacer layer 128 can covers more sidewall surfaces of the fin structure 104. When the second portion 116b of the isolation structure 116 is etched by the pre-clean process, more bottom portion of the fin structure 104 is protected by the fin spacer layer 128. Therefore, the fin structure 104 will not be damaged by the pre-clean process since the fin spacer layer 128 protects the fin structure 104.

After the pre-clean process, the source/drain (S/D) structures 136 are formed in the S/D recesses 130, in accordance with some embodiments. The S/D structures 136 extend above the fin spacer layer 128. The interface between the S/D structures 136 and the fin structure 104 is higher than the bottom surface of the fin spacer layer 128′. [claim 4] In addition, the bottom surface of the fin spacer layer 128′ is lower than the bottom surface of the S/D structure 136.

In some embodiments, the S/D structures 136 are made of any applicable material, such as Ge, Si, GaAs, AlGaAs, SiGe, GaAsP, SiP, SiC, SiCP, or a combination thereof. In some embodiments, the S/D structures 136 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the S/D structures 136 are in-situ doped during the epitaxial growth process. For example, the S/D structures 136 may be the epitaxially grown SiGe doped with boron (B). For example, the S/D structures 136 may be the epitaxially grown Si doped with carbon to form silicon: carbon (Si: C) source/drain features, phosphorous to form silicon: phosphor (Si: P) source/drain features, or both carbon and phosphorous to form silicon carbon phosphor (SiCP) source/drain features. In some embodiments, the S/D structures 136 are doped in one or more implantation processes after the epitaxial growth process.

Next, as shown in FIGS. 2E-1, 2E-2, 2E-3 and 2E-4, after the S/D structures 136 are formed, a contact etch stop layer (CESL) 138 is conformally formed to cover the S/D structures 136 and an interlayer dielectric (ILD) layer 140 is formed over the contact etch stop layers 138, in accordance with some embodiments.

It should be noted that the recessed isolation structure 117 extends into a position which is directly below the gate spacer layer 126 after the pre-clean process, the CESL 138 and the ILD layer 140 are conformally formed on the recessed isolation structure 117. Therefore, a portion of the CESL 138 is directly below the gate spacer layer 126, and a portion of the ILD layer 140 is directly below the gate spacer layer 126, as shown in FIG. 2E-1.

In addition, the recessed isolation structure 117 extends into a position which is directly below the fin spacer layer 128′ after the pre-clean process, and therefore a portion of the CESL 138 is directly below the fin spacer layer 128′, and a portion of the ILD layer 140 is directly below the fin spacer layer 128′, as shown in FIG. 2E-3.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the gate electrode layer 120 of the dummy gate structure 118 are exposed, as shown in FIG. 2H in accordance with some embodiments.

Next, as shown in FIGS. 2F-1, 2F-2, 2F-3 and 2F-4, the dummy gate structure 118 is removed to form a trench 139, and the first semiconductor material layers 106 are removed to form gaps 141, in accordance with some embodiments. As a result, the nanostructures 108′ (or the channel layers 108′) with the second semiconductor material layers 108 are formed.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching. The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions. In some embodiments, the upper portions of the gate spacer layers 126 are also removed

Afterwards, as shown in FIGS. 2G-1, 2G-2, 2G-3 and 2G-4, a gate structure 142 is formed in the trench 139 and the gaps 141, in accordance with some embodiments. More specifically, the dummy gate structure 118 and the first semiconductor material layers 106 are removed to form nanostructures 108′ with the second semiconductor material layers 108, in accordance with some embodiments. The S/D structure 136 is attached to the nanostructures 108′. The bottom surface of the gate spacer layer 126 is lower than the bottom surface of the gate structure 142.

After the nanostructures 108′ are formed, the gate structures 142 are formed wrapped around the nanostructures 108′ (or the channel layers 108′). The gate structures 142 wrap around the nanostructures 108′ to form gate-all-around transistor structures in accordance with some embodiments. The inner spacer layers 134 are between the gate structure 142 and the S/D structure 136.

In some embodiments, the gate structure 142 includes an interfacial layer 144, a gate dielectric layer 146, and a gate electrode layer 148. In some embodiments, the interfacial layers 144 are oxide layers formed around the nanostructures 108′ and on the top of the base fin structure 104B. In some embodiments, the interfacial layers 144 are formed by performing a thermal process.

In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the gate spacer layers 126 and the inner spacer layers 132 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layers 148 are formed on the gate dielectric layer 146. In some embodiments, the gate electrode layers 148 are made of one or more layers of conductive material, such as aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, another suitable material, or a combination thereof. In some embodiments, the gate electrode layers 148 are formed using chemical vapor deposition (CVD), atomic layer deposition (ALD), electroplating, another applicable method, or a combination thereof. Other conductive layers, such as work function metal layers, may also be formed in the gate structures 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate electrode layers 148 are formed, a planarization process such as CMP or an etch-back process may be performed until the ILD layer 140 is exposed.

Afterwards, as shown in FIGS. 2H-1, 2H-2, 2H-3 and 2H-4, an etch stop layer 150 is formed over the gate structure 142, and a dielectric layer 152 is formed over the etch stop layer 150, in accordance with some embodiments. Next, S/D contact structures 156 are formed over the S/D structures 136.

In some embodiments, the contact openings may be formed through the contact etch stop layer 138, the interlayer dielectric layer 140, the etch stop layer 150 and the dielectric layer 152 to expose the top surfaces of the S/D structures 136, and the silicide layers 154 and the S/D contact structure 156 may be formed in the contact openings. The contact openings may be formed using a photolithography process and an etching process. In addition, some portions of the S/D structures 136 exposed by the contact openings may also be etched during the etching process.

After the contact openings are formed, the silicide layers 154 may be formed by forming a metal layer over the top surface of the S/D structures 136 and annealing the metal layer so the metal layer reacts with the S/D structures 136 to form the silicide layers 154. The unreacted metal layer may be removed after the silicide layers 154 are formed.

Afterwards, the liners 158, the barrier layers 160, and the S/D contact structure 156 are formed over the silicide layers 154 in the contact openings and a polishing process is performed. As shown in FIG. 2H-4, the top surface of the S/D contact structure 156 is substantially level with the top surface of the dielectric layer 152, in accordance with some embodiments.

In some embodiments, the etch stop layer 150 is made of a dielectric materials, such as silicon nitride, silicon oxide, silicon oxynitride, another suitable dielectric material, or a combination thereof. The dielectric material for the etch stop layers 150 may be conformally deposited over the semiconductor structure by performing chemical vapor deposition (CVD), atomic layer deposition (ALD), other application methods, or a combination thereof.

In some embodiments, the dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes

In some embodiments, the S/D contact structure 156 are made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the liner 158 is made of silicon nitride, although any other applicable dielectric may be used as an alternative.

In some embodiments, the barrier layer 160 is made of tantalum nitride, although other materials, such as tantalum, titanium, titanium nitride, or the like, may also be used. The liners 158, the barrier layers 160, and the S/D contact structure 156 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

Since the height of the second portion 116b of the isolation structure 116 is reduced, the fin spacer layer 128 can cover more areas of the sidewall surfaces of the fin structure 104. As mentioned above, when the pre-clean process is performed before forming the S/D structure 136, even the second portion 116b of the isolation structure 116 is etched by the pre-clean process, the fin structure 104 is still covered by the fin spacer layer 128. The fin structure 104 exposed by the S/D recess 130 is not damaged to provide a clean surface for forming the S/D structure 136.

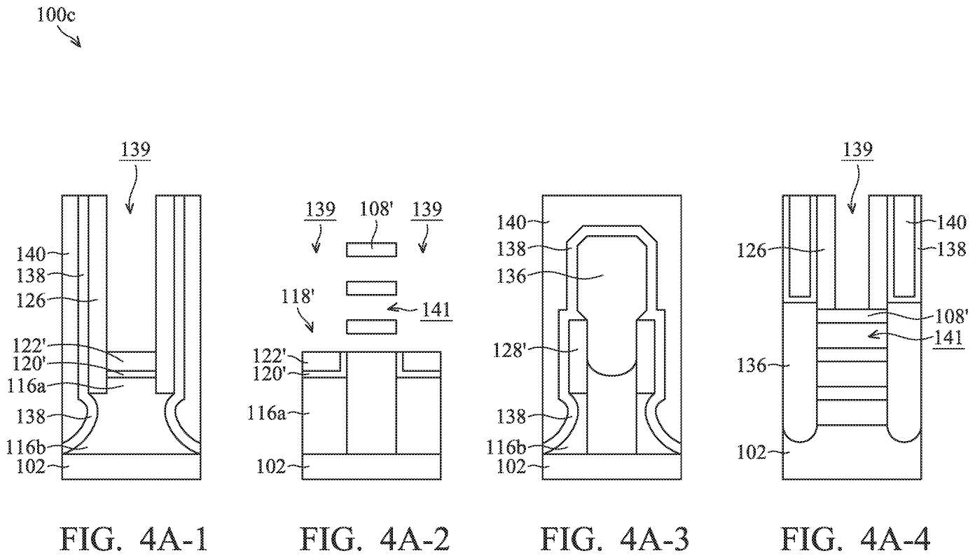

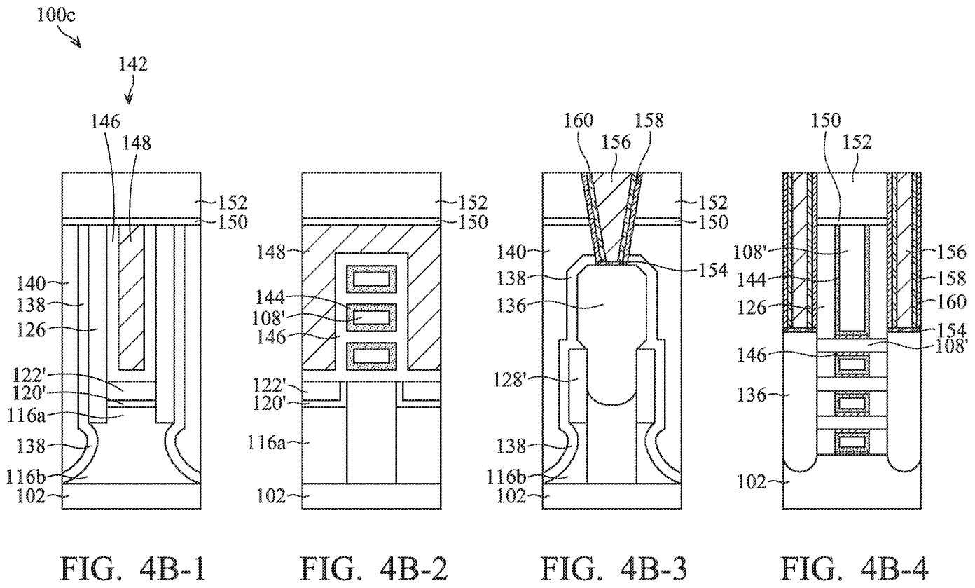

FIGS. 3A-1 to 3B-1 illustrate cross-sectional representations of various stages of manufacturing a semiconductor structure 100b shown along line A-A′ in FIG. 1E, in accordance with some embodiments. FIGS. 3A-2 to 3B-2 illustrate cross-sectional representations of various stages of manufacturing the semiconductor structure 100b shown along line B-B′ in FIG. 1E, in accordance with some embodiments. FIGS. 3A-3 to 3B-3 illustrate cross-sectional representations of various stages of manufacturing the semiconductor structure 100b shown along line C-C′ in FIG. 1E, in accordance with some embodiments. FIGS. 3A-4 to 3B-4 illustrate cross-sectional representations of various stages of manufacturing the semiconductor structure 100b shown along line C-C′ in FIG. 1E, in accordance with some embodiments.

The semiconductor structure 100b includes elements that are similar to, or the same as, elements of the semiconductor structure 100a. The difference between the FIGS. 3A-1, 3A-2 and 3A-3 and FIGS. 2C-1, 2C-2 and 2C-3 is that a bottom isolation layer 135 is formed on the fin structure 104. The bottom isolation layer 135 is used as reduce the leakage from the S/D structure 136 to the substrate 102. The bottom isolation layer 135 have curved bottom surface and curved top surface. In some embodiments, the bottom isolation layer 135 is in direct contact with the first semiconductor layer 106.

As shown in FIGS. 3A-1, 3A-2, 3A-3 and 3A-4, the bottom isolation layer 135 is formed before forming the S/D structure 136, in accordance with some embodiments. The bottom surface of the bottom isolation layer 135 is higher than the bottom surface of the fin spacer layer 128′. In some embodiments, the bottom isolation layer 135 is in direct contact with the inner spacer layer 134.

The bottom isolation layer 135 is made of SiN, SiON, SiOCN, SiOC, SiCN, SiOx, AlOx, HfOx or another applicable material. In some embodiments, the bottom isolation layer 135 is formed by a deposition process, such as CVD process, ALD process, another applicable process, or a combination thereof.

Afterwards, as shown in FIGS. 3B-1, 3B-2, 3B-3 and 3B-4, the S/D structure 136 is formed on the bottom isolation layer 135, and the CESL 138 is formed on the S/D structure 136, in accordance with some embodiments. Next, the ILD layer 140 is formed on the CESL 138, and the dummy gate structure 118 is replaced with the gate structure 142. Afterwards, the S/D contact structure 146 is formed on and is electrically connected to the S/D structure 136.

FIGS. 4A-1 to 4B-1 illustrate cross-sectional representations of various stages of manufacturing a semiconductor structure 100c shown along line A-A′ in FIG. 1E, in accordance with some embodiments. FIGS. 4A-2 to 4B-2 illustrate cross-sectional representations of various stages of manufacturing the semiconductor structure 100c shown along line B-B′ in FIG. 1E, in accordance with some embodiments. FIGS. 4A-3 to 4B-3 illustrate cross-sectional representations of various stages of manufacturing the semiconductor structure 100c shown along line C-C′ in FIG. 1E, in accordance with some embodiments. FIGS. 4A-4 to 4B-4 illustrate cross-sectional representations of various stages of manufacturing the semiconductor structure 100c shown along line C-C′ in FIG. 1E, in accordance with some embodiments.

The semiconductor structure 100c includes elements that are similar to, or the same as, elements of the semiconductor structure 100a. The difference between the FIGS. 4A-1, 4A-2, 4A-3 and 4A-4 and FIGS. 2F-1, 2F-2, 2F-3 and 2F-4 is that dummy gate structure 118 is not completely removed, and the remaining dummy gate structure 118′ is left, in accordance with some embodiments. More specifically, the remaining dummy gate structure 118′ is left on the bottom portion of the trench 139. The remaining dummy gate structure 118′ includes the remaining dummy gate dielectric layer 120′ and the remaining dummy gate electrode layer 122′. The remaining dummy gate structure 118′ is lower than the bottommost nanostructure 108′.

As shown in FIGS. 4B-1, 4B-2, 4B-3 and 4B-4, the gate structure 142 is formed on the remaining dummy gate structure 118′, in accordance with some embodiments. The interfacial layer 144 warps around the nanostructures 108′, and the gate dielectric layer 146 is formed on the interfacial layer 144 and on the remaining dummy gate structure 118′. It should be noted that the gate dielectric layer 146 is in direct contact with the remaining dummy gate structure 118′. The gate dielectric layer 146 is separated from the isolation structure 116 by the remaining dummy gate structure 118′.

Next, the gate electrode layer 148 is formed on the gate dielectric layer 146. Next, the S/D contact structure 156 is formed on and is electrically connected to the S/D structure 136.

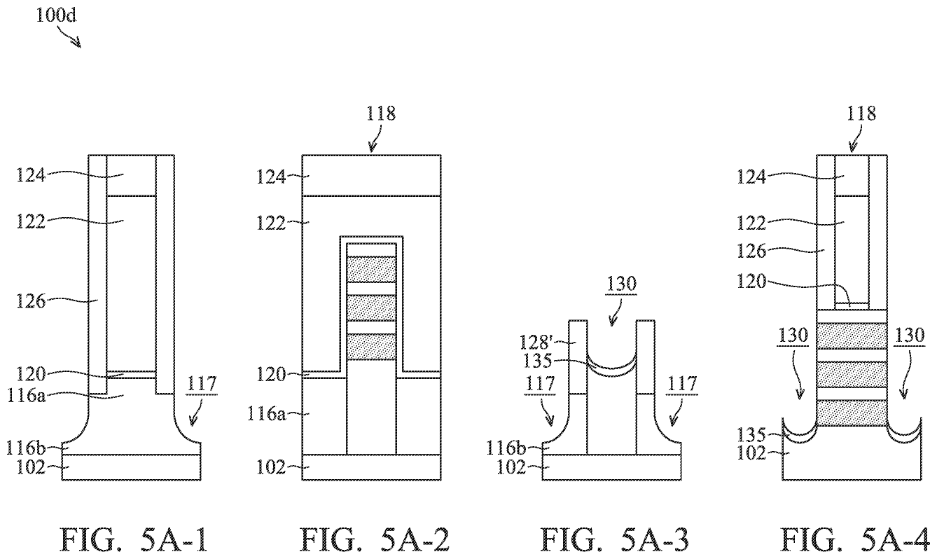

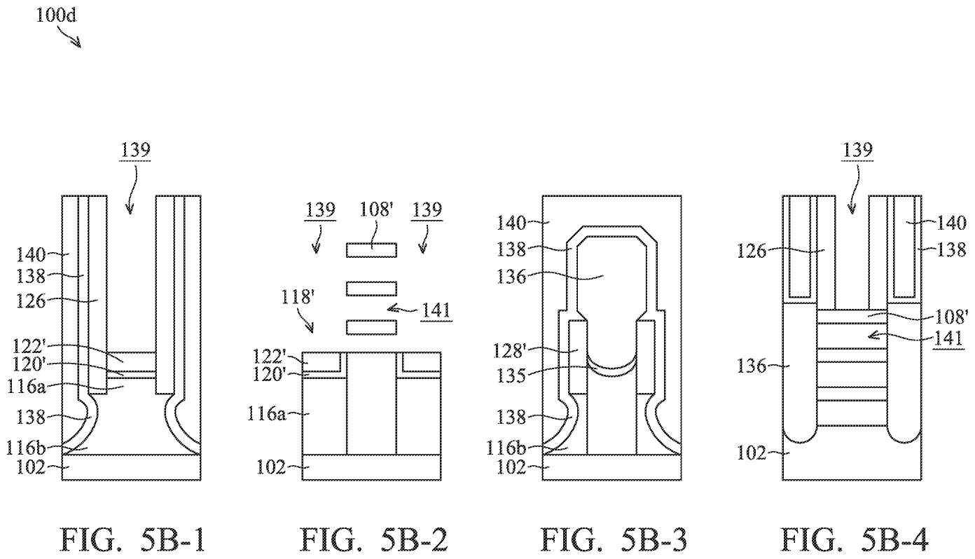

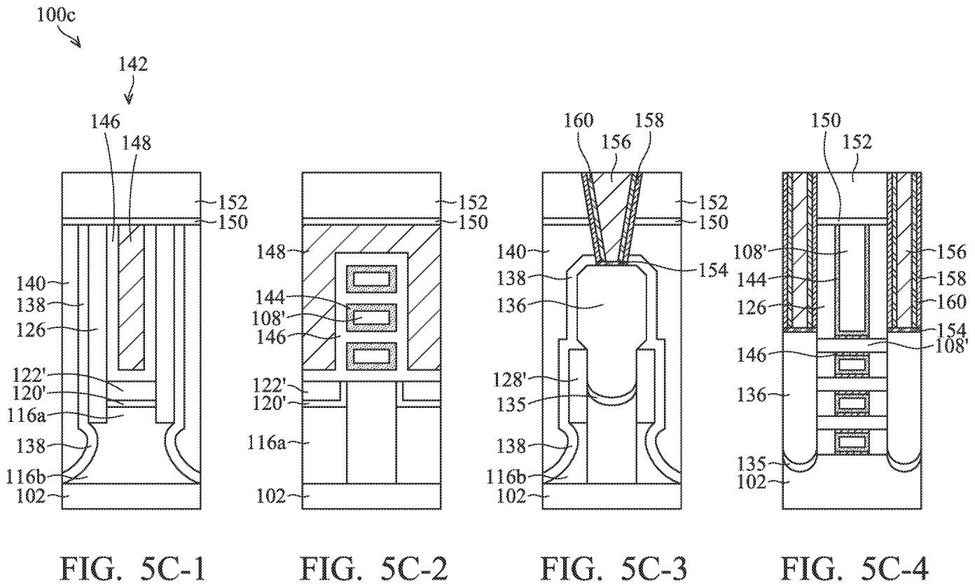

FIGS. 5A-1 to 5C-1 illustrate cross-sectional representations of various stages of manufacturing a semiconductor structure 100d shown along line A-A′ in FIG. 1E, in accordance with some embodiments. FIGS. 5A-2 to 5C-2 illustrate cross-sectional representations of various stages of manufacturing the semiconductor structure 100d shown along line B-B′ in FIG. 1E, in accordance with some embodiments. FIGS. 5A-3 to 5C-3 illustrate cross-sectional representations of various stages of manufacturing the semiconductor structure 100d shown along line C-C′ in FIG. 1E, in accordance with some embodiments. FIGS. 5A-4 to 5C-4 illustrate cross-sectional representations of various stages of manufacturing the semiconductor structure 100d shown along line C-C′ in FIG. 1E, in accordance with some embodiments. The semiconductor structure 100d includes elements that are similar to, or the same as, elements of the semiconductor structure 100a.

The semiconductor structure 100d in FIGS. 5A-1, 5A-2, 5A-3 and 5A-4 is similar to, or the same as, the semiconductor structure 100b in FIGS. 3A-1, 3A-2, 3A-3 and 3A-4. The bottom isolation layer 135 is formed on the fin structure 104. The bottom isolation layer 135 have curved bottom surface and curved top surface.

Next, as shown in FIGS. 5B-1, 5B-2, 5B-3 and 5B-4, the S/D structure 136 is formed on the bottom isolation layer 135. The CESL 138 and ILD layer 140 are formed on the S/D structure 136. Next, a portion of the dummy gate structure 118 is removed to form a trench 139, but the remaining dummy gate structure 118′ is left. The remaining dummy gate structure 118′ is below the bottommost nanostructure 108′. Afterwards, the first semiconductor layers 106 are removed to form the gaps 141. The gaps 141 are above the remaining dummy gate structure 118′.

Afterwards, as shown in FIGS. 5C-1, 5C-2, 5C-3 and 5C-4, the gate structure 142 is formed on the remaining dummy gate structure 118, in accordance with some embodiments. The interfacial layer 144 warps around the nanostructures 108, and the gate dielectric layer 146 is formed on the interfacial layer 144 and on the remaining dummy gate structure 118′. The gate electrode layer 148 is formed on the gate dielectric layer 146. Next, the S/D contact structure 156 is formed on and is electrically connected to the S/D structure 136.

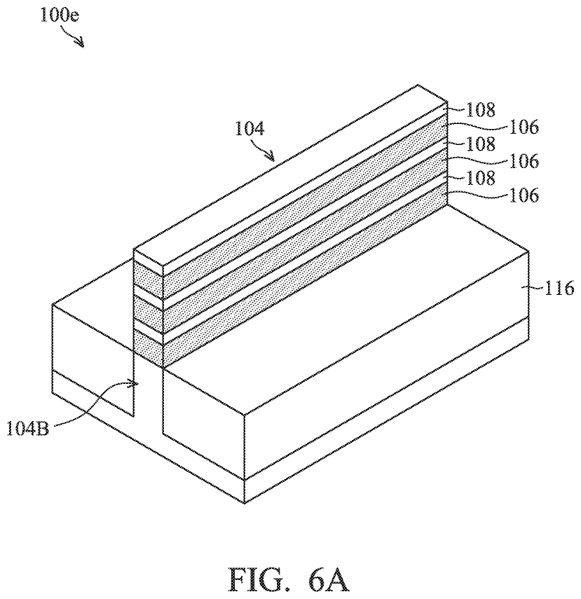

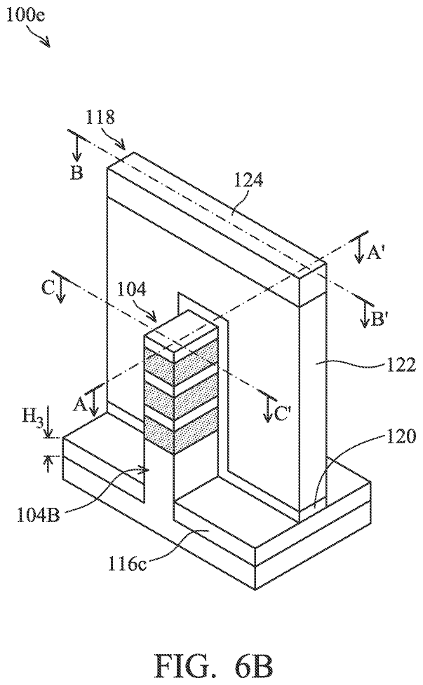

FIGS. 6A to 6B illustrate perspective views of intermediate stages of manufacturing a semiconductor structure 100e, in accordance with some embodiments. As shown in FIG. 6A, first semiconductor material layers 106 and second semiconductor material layers 108 are formed over the substrate 102. Next, the isolation structure 116 is formed around the fin structure 104. The isolation structure 116 has a third height H₃ along the vertical direction. The third height H₃ of the isolation structure 116 is smaller than the second height H₂ of the isolation structure 116 as shown in FIG. 1E.

Next, as shown in FIG. 6B, the dummy gate structure 118 is formed across the fin structure 104 and extend over the isolation structure 116, in accordance with some embodiments. The dummy gate structure 118 may be used to define the source/drain regions and the channel regions of the resulting semiconductor structure 100. In some embodiments, the dummy gate structure 118 includes the dummy gate dielectric layer 120 and the dummy gate electrode layer 122.

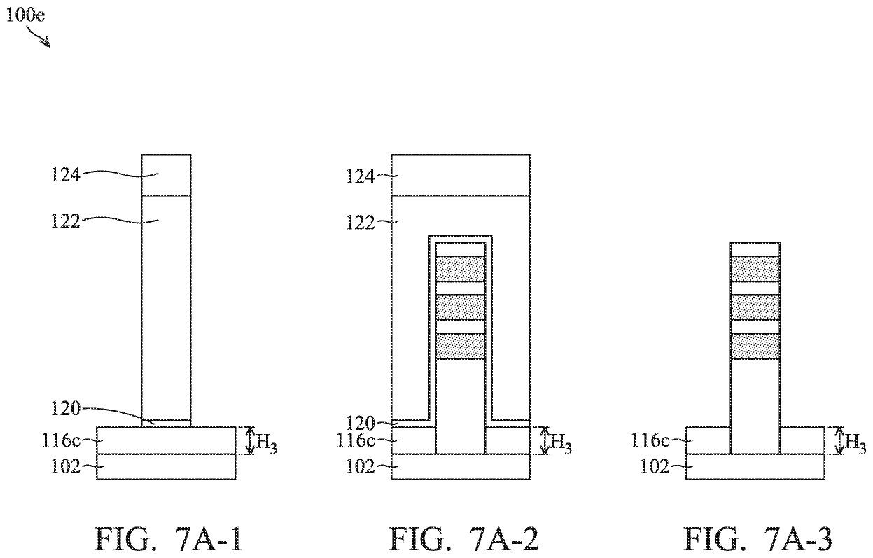

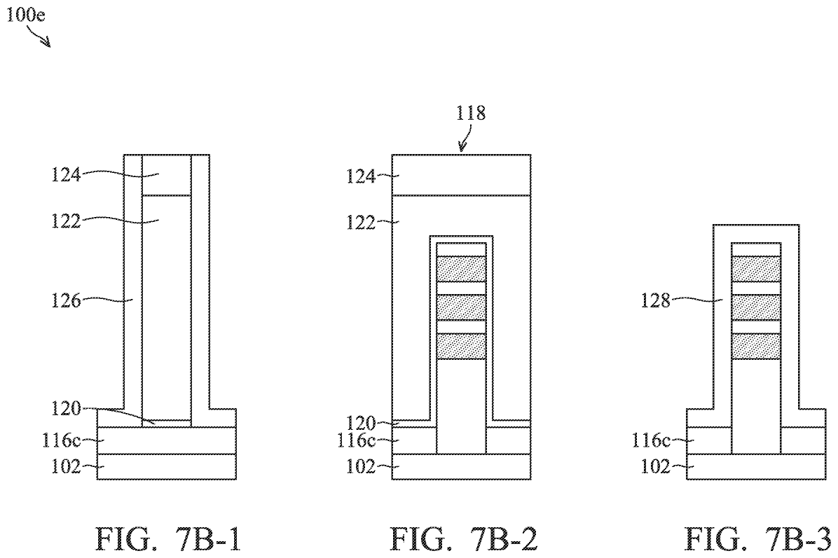

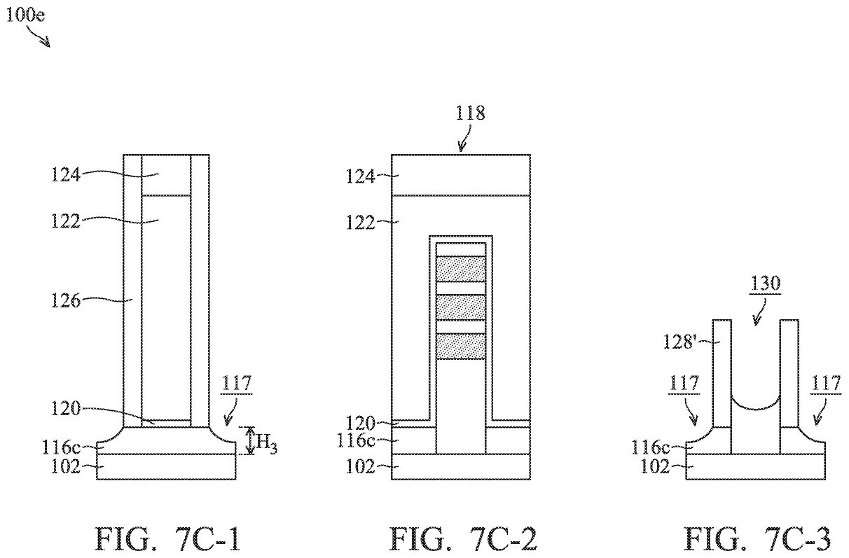

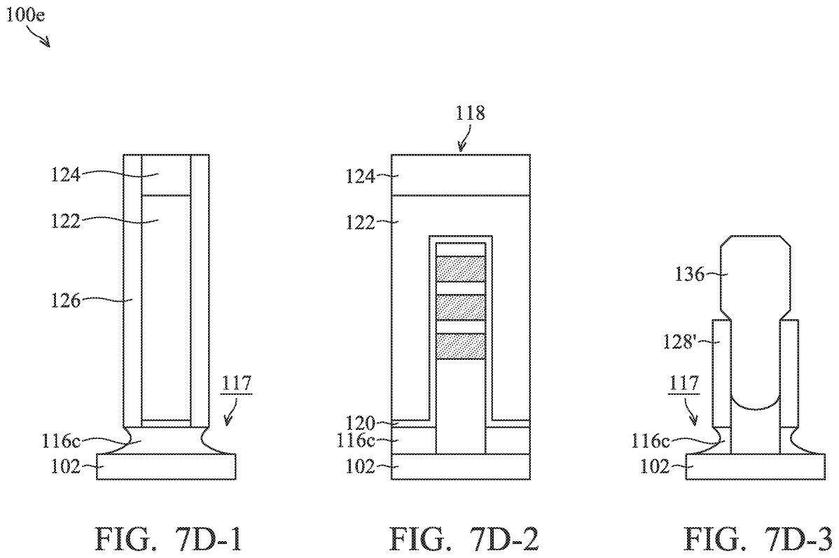

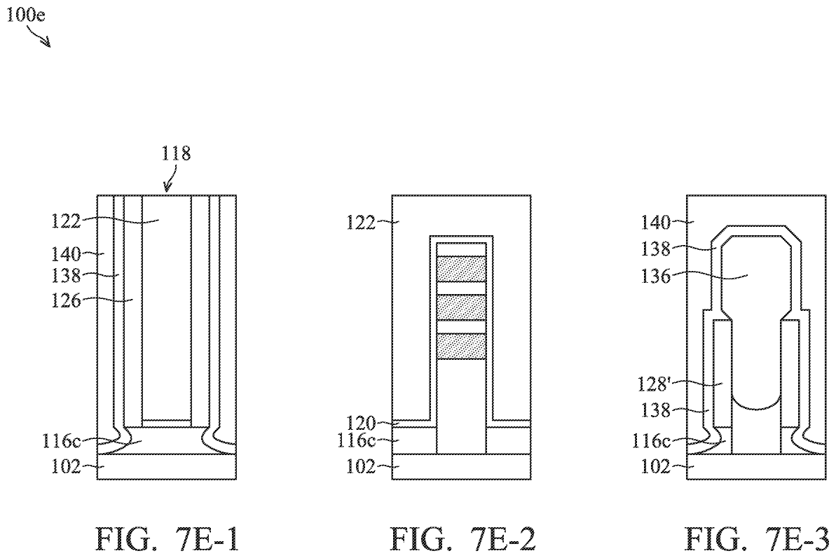

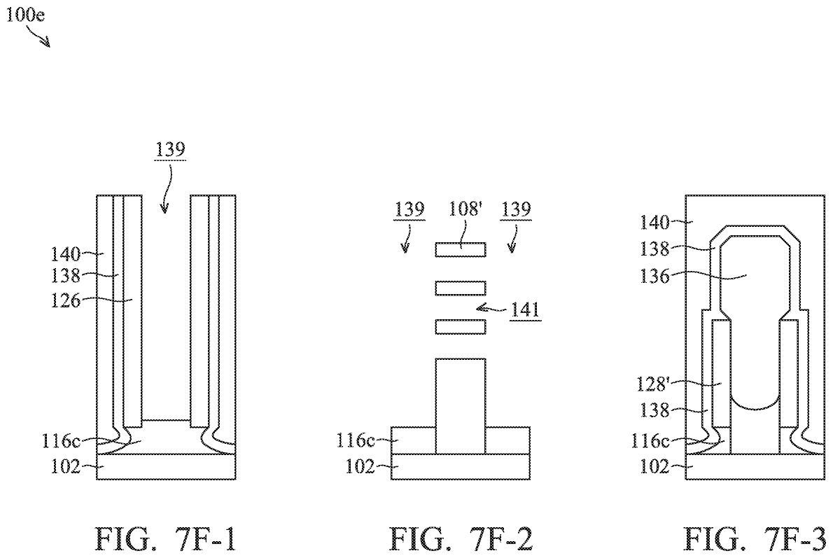

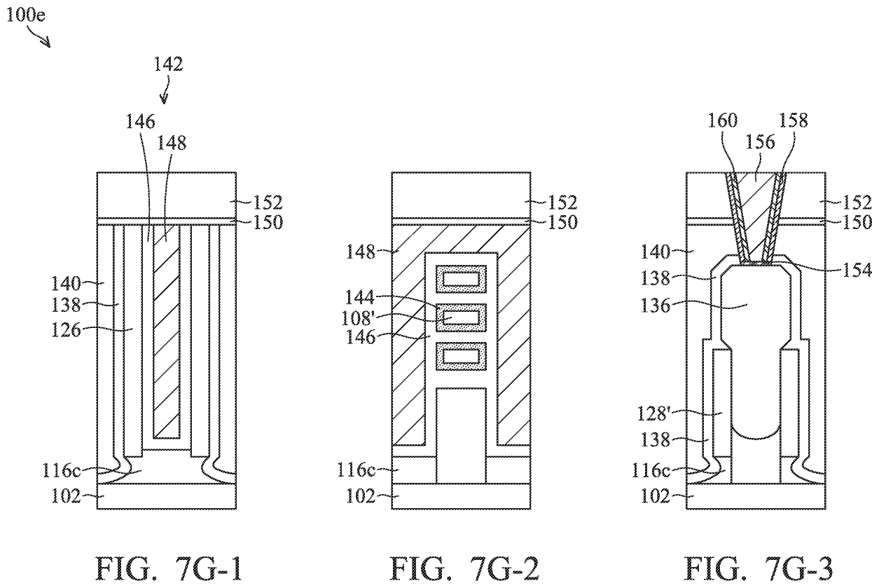

FIGS. 7A-1 to 7G-1 illustrate cross-sectional representations of various stages of manufacturing the semiconductor structure 100e shown along line A-A′ in FIG. 6B, in accordance with some embodiments. FIGS. 7A-2 to 7G-2 illustrate cross-sectional representations of various stages of manufacturing the semiconductor structure 100e shown along line B-B′ in FIG. 6B, in accordance with some embodiments. FIGS. 7A-3 to 7G-3 illustrate cross-sectional representations of various stages of manufacturing the semiconductor structure 100e shown along line C-C′ in FIG. 6B, in accordance with some embodiments.

As shown in FIGS. 7A-1, 7A-2 and 7A-3, the isolation structure 116c has the third height H₃ along the vertical direction. The dummy gate structure 118 is formed on the isolation structure 116c.

Next, as shown in FIGS. 7B-1, 7B-2 and 7B-3, the gate spacer layer 126 are formed along and covering opposite sidewalls of the dummy gate structure 118 and fin spacer layers 128 are formed along and covering opposite sidewalls of the source/drain regions of the fin structure 104, in accordance with some embodiments.

Afterwards, as shown in FIGS. 7C-1, 7C-2 and 7C-3, after the gate spacer layers 126 and the fin spacer layers 128 are formed, the source/drain (S/D) regions of the fin structure 104 are recessed to form source/drain (S/D) recesses 130, as shown in in accordance with some embodiments. In addition, the top portions of the fin spacer layers 128 are removed to form the fin spacer layers 128′, and a portion of the isolation structure 116c is removed to form the isolation recess 117.

More specifically, the first semiconductor material layers 106 and the second semiconductor material layers 108 not covered by the dummy gate structure 118 and the gate spacer layers 126 are removed, in accordance with some embodiments.

Next, as shown in FIGS. 7D-1, 7D-2 and 7D-3, the pre-clean process is formed on the exposed top surface of the fin structure 104, and the source/drain (S/D) structures 136 are formed in the S/D recesses 130, in accordance with some embodiments. The S/D structures 136 extend above the fin spacer layer 128. The interface between the S/D structures 136 and the fin structure 104 is higher than the bottom surface of the fin spacer layer 128′.

It should be noted that although the isolation structure 116c may be etched during the pre-clean process, the fin structure 104 is not damaged by the pre-clean process since the fin spacer layer 128′ protects the bottom portion of the fin structure 104.

Afterwards, as shown in FIGS. 7E-1, 7E-2 and 7E-3, after the S/D structures 136 are formed, a contact etch stop layer (CESL) 138 is conformally formed to cover the S/D structures 136 and an interlayer dielectric (ILD) layer 140 is formed over the contact etch stop layers 138, in accordance with some embodiments. Note that a portion of the CESL 138 is directly below the gate spacer layer 126 and directly below the fin spacer layer 128′. In addition, a portion of the ILD layer 140 is directly below the gate spacer layer 126 and directly below the fin spacer layer 128′.

Next, as shown in FIGS. 7F-1, 7F-2 and 7F-3, the dummy gate structure 118 are removed to form a trench 139, and the first semiconductor material layers 106 are removed to form gaps 141, in accordance with some embodiments. As a result, the nanostructures 108′ (or the channel layers 108′) with the second semiconductor material layers 108 are formed.

Afterwards, as shown in FIGS. 7G-1, 7G-2 and 7G-3, the gate structure 142 is formed in the trench 139 and the gaps 141, in accordance with some embodiments. More specifically, the dummy gate structure 118 and the first semiconductor material layers 106 are removed to form nanostructures 108′ with the second semiconductor material layers 108, in accordance with some embodiments. The S/D structure 136 is attached to the nanostructures 108′. In some embodiments, the gate structure 142 includes the interfacial layer 144, the gate dielectric layer 146, and the gate electrode layer 148. Next, the S/D contact structure 146 is formed on and is electrically connected to the S/D structure 136.

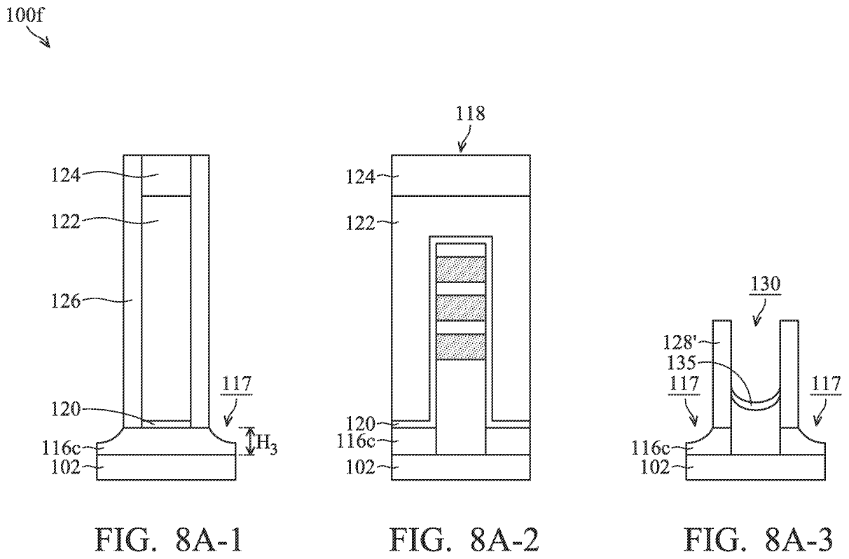

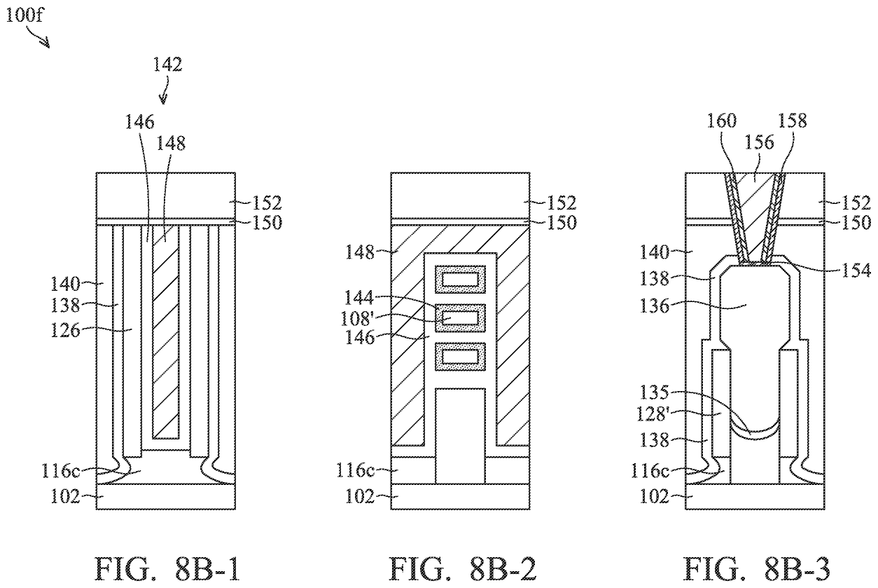

FIGS. 8A-1 to 8B-1 illustrate cross-sectional representations of various stages of manufacturing a semiconductor structure 100f shown along line A-A′ in FIG. 6B, in accordance with some embodiments. FIGS. 8A-2 to 8B-2 illustrate cross-sectional representations of various stages of manufacturing the semiconductor structure 100f shown along line B-B′ in FIG. 6B, in accordance with some embodiments. FIGS. 8A-3 to 8B-3 illustrate cross-sectional representations of various stages of manufacturing the semiconductor structure 100f shown along line C-C′ in FIG. 6B, in accordance with some embodiments.

The semiconductor structure 100f includes elements that are similar to, or the same as, elements of the semiconductor structure 100e. The difference between the FIGS. 8A-1, 8A-2 and 8A-3 and FIGS. 7C-1, 7C-2 and 7C-3 is that the bottom isolation layer 135 is formed on the fin structure 104. The bottom isolation layer 135 is used as reduce the leakage from the S/D structure 136 to the substrate 102.

As shown in FIGS. 8A-1, 8A-2 and 8A-3, the bottom isolation layer 135 is formed before forming the S/D structure 136, in accordance with some embodiments. The bottom surface of the bottom isolation layer 135 is higher than the bottom surface of the fin spacer layer 128′. In some embodiments, the bottom isolation layer 135 is in direct contact with the inner spacer layer 134.

Next, as shown in FIGS. 8B-1, 8B-2 and 8B-3, the S/D structure 136 is formed on the bottom isolation layer 135, and the CESL 138 is formed on the S/D structure 136, in accordance with some embodiments. Next, the ILD layer 140 is formed on the CESL 138, and the dummy gate structure 118 is replaced with the gate structure 142. Afterwards, the S/D contact structure 146 is formed on and is electrically connected to the S/D structure 136.

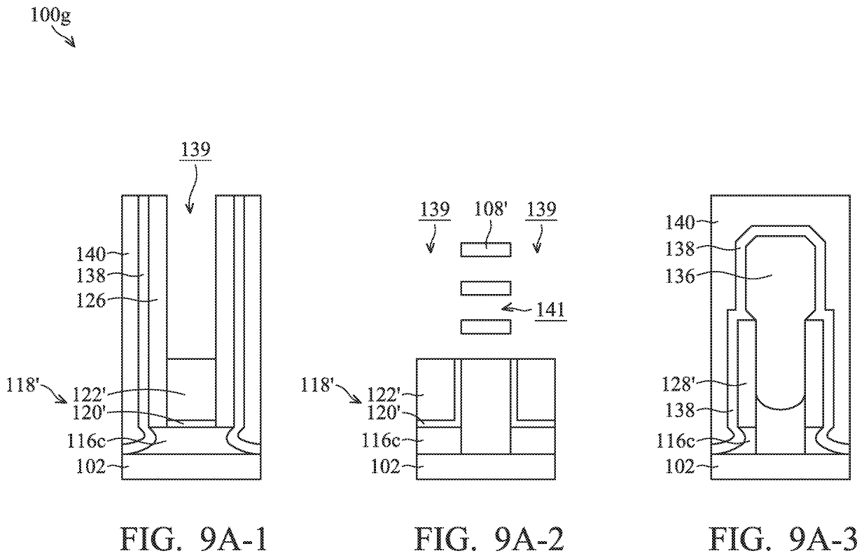

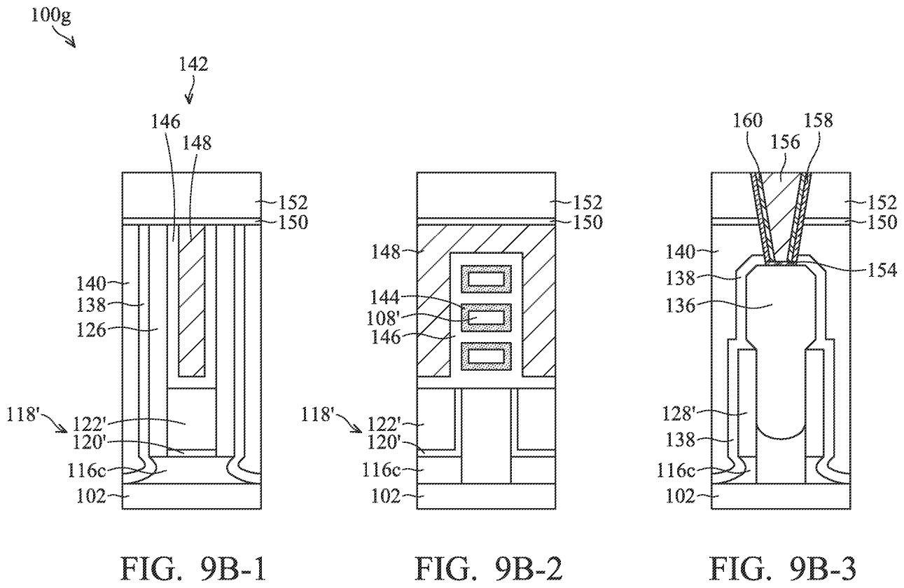

FIGS. 9A-1 to 9B-1 illustrate cross-sectional representations of various stages of manufacturing a semiconductor structure 100g shown along line A-A′ in FIG. 6B, in accordance with some embodiments. FIGS. 9A-2 to 9B-2 illustrate cross-sectional representations of various stages of manufacturing the semiconductor structure 100g shown along line B-B′ in FIG. 6B, in accordance with some embodiments. FIGS. 9A-3 to 9B-3 illustrate cross-sectional representations of various stages of manufacturing the semiconductor structure 100g shown along line C-C′ in FIG. 6B, in accordance with some embodiments.

The semiconductor structure 100g includes elements that are similar to, or the same as, elements of the semiconductor structure 100e. The difference between the FIGS. 9A-1, 9A-2 and 9A-3 and FIGS. 7F-1, 7F-2 and 7F-3 is that dummy gate structure 118 is not completely removed, and the remaining dummy gate structure 118′ is left, in accordance with some embodiments. More specifically, the remaining dummy gate structure 118′ is left on the bottom portion of the trench 139.

Next, as shown in FIGS. 9B-1, 9B-2 and 9B-3, the gate structure 142 is formed on the remaining dummy gate structure 118′, in accordance with some embodiments. The interfacial layer 144 warps around the nanostructures 108′, and the gate dielectric layer 146 is formed on the interfacial layer 144 and on the remaining dummy gate structure 118′.

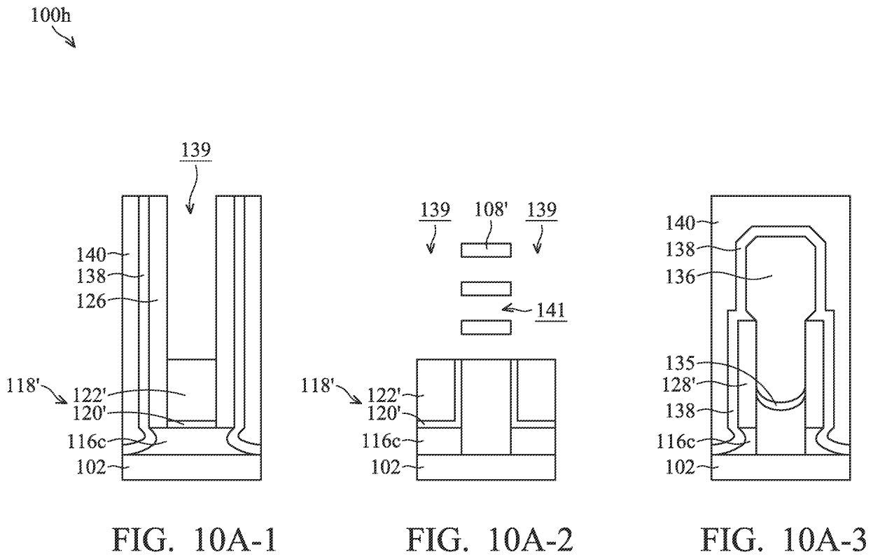

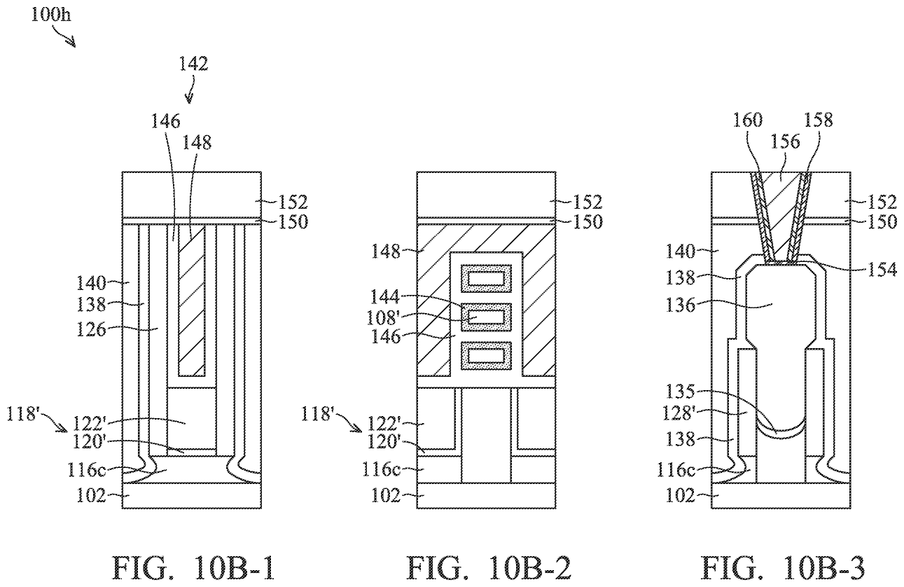

FIGS. 10A-1 to 10B-1 illustrate cross-sectional representations of various stages of manufacturing a semiconductor structure 100h shown along line A-A′ in FIG. 6B, in accordance with some embodiments. FIGS. 10A-2 to 10B-2 illustrate cross-sectional representations of various stages of manufacturing the semiconductor structure 100h shown along line B-B′ in FIG. 6B, in accordance with some embodiments. FIGS. 10A-3 to 10B-3 illustrate cross-sectional representations of various stages of manufacturing the semiconductor structure 100h shown along line C-C′ in FIG. 6B, in accordance with some embodiments.

The semiconductor structure 100h in FIGS. 10A-1, 10A-2 and 10A-3 is similar to, or the same as, the semiconductor structure 100b in FIGS. 7C-1, 7C-2 and 7C-3. The bottom isolation layer 135 is formed on the fin structure 104. The bottom isolation layer 135 have curved bottom surface and curved top surface.

Next, as shown in FIGS. 10B-1, 10B-2 and 10B-3, the S/D structure 136 is formed on the bottom isolation layer 135. The CESL 138 and ILD layer 140 are formed on the S/D structure 136. Next, a portion of the dummy gate structure 118 is removed to form a trench 139, but the remaining dummy gate structure 118′ is left. The remaining dummy gate structure 118′ is below the bottommost nanostructure 108′. Afterwards, the first semiconductor layers 106 are removed to form the gaps 141. The gaps 141 are above the remaining dummy gate structure 118′.

Afterwards, the gate structure 142 is formed on the remaining dummy gate structure 118, in accordance with some embodiments. The interfacial layer 144 warps around the nanostructures 108, and the gate dielectric layer 146 is formed on the interfacial layer 144 and on the remaining dummy gate structure 118′. The gate electrode layer 148 is formed on the gate dielectric layer 146. Next, the S/D contact structure 156 is formed on and is electrically connected to the S/D structure 136.

As mentioned above, the isolation structure 116a includes a first portion 116a which is directly below the dummy gate structure 118. A portion of the isolation structure 116 which is not covered by the dummy gate structure 118 is removed to form a second portion 116b of isolation structure 116. The first portion 116a of the isolation structure has a first height H₁, and the second portion 116b of the isolation structure 116 has a second height H₂. The gate spacer layer 126 is formed on sidewall surfaces of the dummy gate structure 118. At the S/D regions, the top portion of the fin structure 104 is removed to form the S/D recess 130. The fin spacer layer 128 is formed on the sidewall surface of the fin structure 104 in the S/D regions. Since the second portion 116b of the isolation structure 116 is lower than the first portion 116a, the bottom portion of the fin structure 104 is protected by the fin spacer layer 128, and the fin structure 104 is not damaged or etched, the S/D structure 136 can be formed in the S/D recess 130 and on the fin structure 104. Therefore, the performance of the semiconductor structure may be improved.

It should be noted that same elements in FIGS. 1A to 10B-3 may be designated by the same numerals and may include similar or the same materials and may be formed by similar or the same processes; therefore such redundant details are omitted in the interest of brevity. In addition, although FIGS. 1A to 10B-3 are described in relation to the method, it will be appreciated that the structures disclosed in FIGS. 1A to 10B-3 are not limited to the method but may stand alone as structures independent of the method. Similarly, although the methods shown in FIGS. 1A to 10B-3 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The nanostructures are formed on a substrate, and a gate structure wraps around the nanostructures. The gate spacer layers are formed on opposite sidewall surfaces of the gate structure. The fin spacer layers protect the fin structure in the S/D region, and the gate spacer layer protects the fin structure in the gate region. Before forming the S/D structure, the pre-clean process is performed. The isolation structure may be etched by the pre-clean process, but the fin structure is protected by the fin spacer layers or the gate spacer layers. The fin structure is not etched or damaged by the pre-clean process, and the S/D structure can be formed on the fin structure. Therefore, the performance of the semiconductor structure may be improved.

In some embodiments, a semiconductor structure is provided. The semiconductor structure includes a plurality of nanostructures formed over a substrate, and a gate structure formed on the nanostructures. The semiconductor structure includes a source/drain (S/D) structure formed adjacent to the gate structure, and a fin spacer layer adjacent to the S/D structure. The bottom surface of the fin spacer layer is lower than a bottom surface of the S/D structure.

In some embodiments, a semiconductor structure is provided. The semiconductor structure includes an isolation structure formed over a substrate, and a plurality of nanostructures formed over the isolation structure. The semiconductor structure includes a gate structure formed on the nanostructures, and the isolation structure includes a first portion directly below the gate structure and a second portion outside the gate structure, the first portion has a first height, the second portion has a second height, and the first height is greater than the second height.

In some embodiments, a method for forming a semiconductor structure is provided. The method includes forming a stack layer on a substrate, and the stack layer comprises a plurality of first semiconductor material layers and a plurality of second semiconductor material layers alternately stacked. The method includes forming an isolation structure over the substrate, and the stack layer extends above the isolation structure. The method also includes forming a dummy gate structure over the first semiconductor material layers and the second semiconductor material layers. The method further includes performing an etching process on the isolation structure, and the isolation structure after the etching process comprises a first portion directly below the dummy gate structure and a second portion outside the dummy gate structure, and a top surface of the second portion is lower than a top surface of the first portion. The method includes removing a portion of the first semiconductor material layers and a portion of second semiconductor material layers to form an S/D recess, and a portion of the isolation structure is removed to form an isolation recess when forming the S/D recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of nanostructures formed over a substrate;
a gate structure formed on the nanostructures;
a source/drain (S/D) structure formed adjacent to the gate structure; and
a fin spacer layer adjacent to the S/D structure, wherein a bottom surface of the fin spacer layer is lower than a bottom surface of the S/D structure.

2. The semiconductor structure as claimed in claim 1, further comprising:
an isolation structure formed over the substrate, wherein the isolation structure comprises a first portion directly below the gate structure and a second portion outside the gate structure, and the first portion has a first height, the second portion has a second height, and the first height is greater than the second height.

3. The semiconductor structure as claimed in claim 2, wherein the second portion of the isolation structure has a curved sidewall surface.

4. The semiconductor structure as claimed in claim 1, wherein the S/D structure is formed on the substrate, and an interface between the substrate and the S/D structure is higher than the bottom surface of the fin spacer layer.

5. The semiconductor structure as claimed in claim 1, further comprising:
a gate spacer layer formed on a sidewall surface of the gate structure, wherein a bottom surface of the gate spacer layer is lower than a bottom surface of the gate structure.

6. The semiconductor structure as claimed in claim 1, further comprising:
a bottom isolation layer below the S/D structure, wherein a bottom surface of the bottom isolation layer is higher than the bottom surface of the fin spacer layer.

7. The semiconductor structure as claimed in claim 1, further comprising:
a dummy gate structure between the gate structure and the substrate, wherein the dummy gate structure is below a bottommost nanostructure.

8. The semiconductor structure as claimed in claim 1, further comprising:
an etching stop layer formed on the S/D structure and the fin spacer layer, wherein a portion of the etching stop layer is lower than the bottom surface of the fin spacer layer.

9. The semiconductor structure as claimed in claim 8, further comprising:
a dielectric layer formed on the etching stop layer, wherein a portion of the dielectric layer is lower than the bottom surface of the fin spacer layer.

10. A semiconductor structure, comprising:
an isolation structure formed over a substrate;
a plurality of nanostructures formed over the isolation structure; and
a gate structure formed on the nanostructures, wherein the isolation structure comprises a first portion directly below the gate structure and a second portion outside the gate structure, and the first portion has a first height, the second portion has a second height, and the first height is greater than the second height.

11. The semiconductor structure as claimed in claim 10, further comprising:
a gate spacer layer formed on a sidewall surface of the gate structure, wherein a bottom surface of the gate spacer layer is lower than a bottom surface of the gate structure.

12. The semiconductor structure as claimed in claim 11, further comprising:
an etching stop layer formed on the gate spacer layer, wherein a portion of the etching stop layer is lower than a bottom surface of the gate spacer layer.

13. The semiconductor structure as claimed in claim 12, further comprising:
a dielectric layer formed on the etching stop layer, wherein a portion of the dielectric layer is lower than the bottom surface of the gate spacer layer.

14. The semiconductor structure as claimed in claim 10, further comprising:
an inner spacer layer between two adjacent nanostructures; and
a source/drain (S/D) structure formed adjacent to the inner spacer layer, wherein an inner spacer layer is between the S/D structure and the gate structure.

15. The semiconductor structure as claimed in claim 14, further comprising:
a dummy gate structure between the gate structure and the substrate, wherein the dummy gate structure is below a bottommost nanostructure.

16. A method for forming a semiconductor structure, comprising:
forming a stack layer on a substrate, wherein the stack layer comprises a plurality of first semiconductor material layers and a plurality of second semiconductor material layers alternately stacked;
forming an isolation structure over the substrate, wherein the stack layer extends above the isolation structure;
forming a dummy gate structure over the first semiconductor material layers and the second semiconductor material layers;
performing an etching process on the isolation structure, wherein the isolation structure after the etching process comprises a first portion directly below the dummy gate structure and a second portion outside the dummy gate structure, and a top surface of the second portion is lower than a top surface of the first portion; and
removing a portion of the first semiconductor material layers and a portion of second semiconductor material layers to form an S/D recess, wherein a portion of the isolation structure is removed to form an isolation recess when forming the S/D recess.

17. The method for forming the semiconductor structure as claimed in claim 16, further comprising:
forming a fin spacer layer adjacent to the stack layer; and
forming an S/D structure in the S/D recess, wherein the S/D structure is formed adjacent to the fin spacer layer, and a bottom surface of the fin spacer layer is lower than a bottom surface of the S/D structure.

18. The method for forming the semiconductor structure as claimed in claim 17, further comprising:
forming a bottom isolation layer in the S/D recess before forming the S/D structure, wherein the bottom isolation layer has a curved top surface.

19. The method for forming the semiconductor structure as claimed in claim 16, further comprising:
forming a gate spacer layer adjacent to the dummy gate structure, wherein a bottom surface of the gate spacer layer is lower than a bottom surface of the dummy gate structure.

20. The method for forming the semiconductor structure as claimed in claim 16, further comprising:
removing a portion of the dummy gate structure to form a remaining dummy gate structure;
removing the remaining second semiconductor material layers to form a gap; and
forming a gate structure in the gap, wherein the gate structure is formed on the remaining dummy gate structure.
